(19) United States
(12) Patent Application Publication
(10) Pub. No.: US 2026/0244838 A1
(43) Pub. Date: Aug. 20, 2026

(54) GENERATIVE AI ASSISTANT FOR ANALOG CIRCUIT DESIGN

(71) Applicant: GlobalFoundries Singapore Pte. Ltd., Singapore (SG)

(72) Inventors: Muhammad Arsyad Leong Bin ABDULLAH, Singapore (SG); Romain FEUILLETTE, Williston, VT (US); Mariya Bozhidarova STANOEVA, Sofia (BG); Toshko MILADINOV, Sofia (BG); Simona Milenova DIMITROVA, Sofia (BG); Aleks-Martin Konstantinov LAKOVSKI, Sofia (BG); Seniha Metin RUPKINA, Sofia (BG); Mihail Yanchev VALCHEV, Sofia (BG); Kiril IVANOV, Sofia (BG); Georgi Stoyanov HRISTOV, Sofia (BG); Nolan PAVEK, Malta, NY (US); Farzana AKHTER, Colorado Springs, CO (US); Nikola DINKOV, Sofia (BG)

(21) Appl. No.: 19/056,332

(22) Filed: Feb. 18, 2025

(51) Int. Cl. G06F 30/392; G06N 3/0475; G06N 3/08

(52) U.S. Cl. CPC G06F 30/392; G06N 3/0475; G06N 3/08

(57) ABSTRACT

A semiconductor design method performed by a computer comprises receiving an indication of a device comprising a parameterized cell (pcell), receiving a prompt regarding the device, and producing, using a trained machine learning (ML) model and based on the indication of the device and the prompt, a first value for a first parameter of the device. The trained ML model may be a generative artificial intelligence ML model. The method may also comprise receiving a partial input including a second value for a second parameter of the device and producing, using the trained ML model and based on the indication of the device, the prompt, and the partial input, the first value for the first parameter of the device. The first parameter may be a parameter used to configure the pcell, a layout placement parameter for the device, or a parameter for setting up a simulation of the device.

### FIELD OF THE DISCLOSURE

The present disclosure relates to Computer-Aided Design (CAD) systems, and specifically to CAD systems for designing analog electronic circuits.

### BACKGROUND

Analog electronic circuits (hereinafter, analog circuits) receive, process, and/or generate signals having a continuous range of values expressed as a voltage or current.

In comparison to digital electronic circuits (hereinafter, digital circuits), where each signal has a discrete number of values (commonly 2), analog circuits lack the inherent high level of resistance to noise, distortion, interference, temperature changes, supply voltage changes, process variations, and so on that digital circuits possess.

The need to overcome this lack of resistance adds additional complexity to analog circuit design. This complexity may be exhibited in the large number of parameters that must be set when designing an analog circuit. For example, when designing an integrated circuit including an analog circuit including a transistor, it is not unusual for a designer to have to specify multiple physical qualities of that transistor, including channel dimensions, gate electrode geometry, and the like. The values chosen for these parameters may depend on a large number of factors, including, for example, the semiconductor process or processes that the analog circuit is intended to be fabricated, the operating environment of the analog circuit, and what other circuits are included in the integrated circuit.

Electronic Design Automation (EDA) systems may ease the task of entering these values, but EDA systems of the related arts do not provide much help in determining them.

As a result, the design of analog circuits if more difficult than the design of digital circuits. Furthermore, people having a high level of skill in the design of analog circuits can be difficult to find.

Accordingly, there exists a need for an EDA system that assists designers with the process of determining appropriate design parameters for devices in analog circuits.

### SUMMARY

Embodiments of the present disclosure relate to systems and methods for EDA systems. In particular, embodiments relate to EDA systems for designing an analog circuit wherein a designer is tasked with selecting values for parameters of devices in the analog circuit.

In an embodiment, a computer performs a method for semiconductor design, the method comprising receiving an indication of a device comprising a parameterized cell (pcell), receiving a prompt regarding the device, and producing, using a trained machine learning (ML) model and based on the indication of the device and the prompt, a first value for a first parameter of the device.

In an embodiment, a non-transient computer-readable medium comprises computer programming instructions which, when executed by a computer, cause the computer to perform a method for semiconductor design, the method comprising receiving an indication of a device comprising a parameterized cell (pcell), receiving a prompt regarding the device, and producing, using a trained machine learning (ML) model and based on the indication of the device and the prompt, a first value for a first parameter of the device.

In embodiments, the trained ML model is a generative artificial intelligence (AI) ML model.

In embodiments, the method further comprises receiving a partial input including a second value for a second parameter of the device, and producing, using the trained ML model and based on the indication of the device, the prompt, and the partial input, the first value for the first parameter of the device.

In embodiments, the method further comprises communicating, using a user interface, a message including the first value, receiving, using the user interface, a response to the message, when the response indicates that the first value is accepted, setting the first parameter to the first value, and when the response indicates that the first value is rejected, producing, using the trained ML model and based on the indication of the device and the prompt, a second value for the first parameter of the device.

### BRIEF DESCRIPTION OF THE DRAWINGS

The accompanying drawings, which are incorporated in and constitute a part of this specification, illustrate various embodiments of the invention and, together with a general description of the invention given above and the detailed description of the embodiments given below, serve to explain the embodiments of the invention. In the drawings, like reference numerals refer to like features in the various views.

FIG. 1 illustrates a system for design electronic devices according to an embodiment.

FIG. 2 illustrates a process according to an embodiment for determining parameter values for devices in analog circuits.

FIG. 3A illustrates an interface for setting parameter values.

FIG. 3B illustrates an interface for setting parameter values according to an embodiment.

FIG. 4 includes an interface for entering a prompt according to an embodiment.

### DETAILED DESCRIPTION

Illustrative embodiments of the present disclosure will be described below in more detail with reference to the accompanying drawings. The inventive features may, however, be embodied in different forms and should not be construed as limited to the embodiments set forth herein. Rather, these embodiments are provided so that this disclosure will be thorough and complete, and will fully convey the scope of the present claims to those skilled in the art. Throughout the disclosure, like reference numerals refer to like parts throughout the various figures and embodiments.

It will be understood that, although the terms “first” and/or “second” may be used herein to describe various elements, these elements should not be limited by these terms. These terms are only used to distinguish one element from another element. For instance, a first element discussed below could be termed a second element without departing from the teachings of the present disclosure. Similarly, the second element could also be termed the first element. Furthermore, in the following, a “set” of items refers to one or more of the items, and a “plurality” of items refers to two or more of the items.

The drawings are not necessarily to scale and in some instances, proportions may have been exaggerated in order to clearly illustrate features of the embodiments.

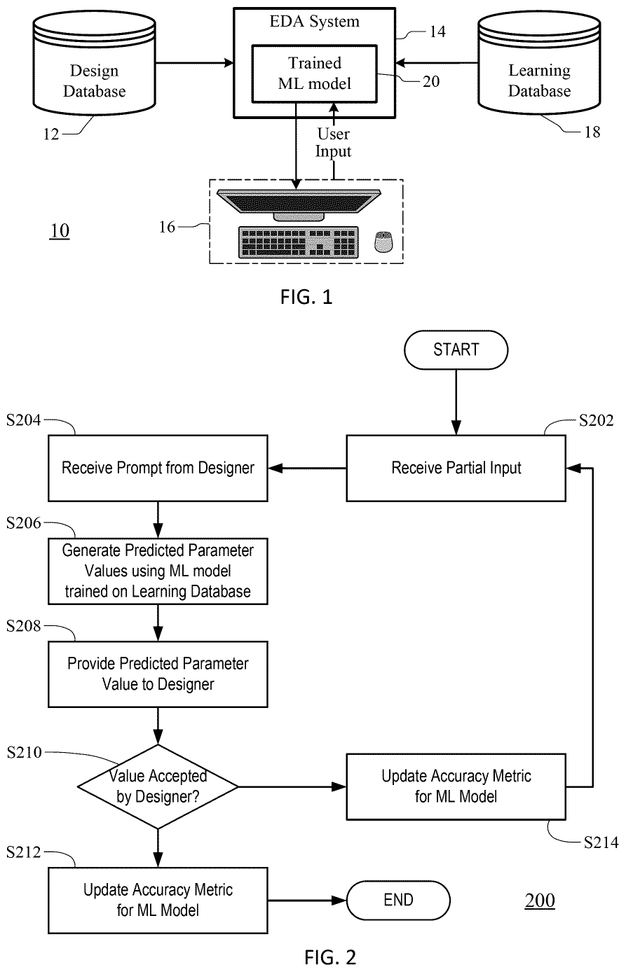

FIG. 1 illustrates a system 10 for design electronic devices according to an embodiment.

The system 10 comprises a design database 12, and EDA system 14, a human interaction device (HID) 16, a learning database 18, and one or more trained machine learning (ML) models 20 (hereinafter, ML model 20).

The EDA system 14 presents a design stored in the design database 12 to a user via the HID 16, and may permit a user (e.g., a designer) to inspect, evaluate, and modify the design. The EDA system may interact with the user through a Graphical User Interface (GUI) presented through the HID 16.

The HID 16 may be any of a variety of user interface devices capable of presenting images to a user and of receiving inputs from the user. For example, the HID 16 may include one or more selected from a group comprising a monitor, a touch-screen display, a mouse, a keyboard, a trackpad, a digitizer tablet, a trackball, a keypad, a speaker, a microphone, a gesture recognition subsystem, and the like, but embodiments are not limited thereto.

Through the HID 16, the user may provide to the ML model 20 a selection of a device for modification from the design database 12, may optionally provide one or more values for parameters of the device that the user has set, and provides a prompt to the ML model 20.

In response to the prompt, the ML model 20 will determine values for parameters of the device not yet set by the user according to the already-set parameter values, the contents of the prompt, and the training produced based on the learning database 18.

The user may then accept or reject any or all of the values provided by the ML model 20, and if not all values provided by the ML model 20 are accepted, may add any accepted values to the one or more values for parameters of the device that the user has set and then prompt the ML model 20 again.

In this manner, ML model 20 aides the user in selection of appropriate values for devices in an analog circuit, resulting in reduced time spent completing the design and in fewer errors in entry of the values for the parameters.

FIG. 2 illustrates a process 200, according to an embodiment, for determining parameter values for devices in an analog circuits. The process may be performed by the EDA system 14 of FIG. 1.

At S202, the process 200 receives a partial input comprising an indication of a design database corresponding to a circuit, a selection of a device in the circuit, and optionally one or more values for parameters of the device. The design database may include layout information, process information, and other information about the circuit.

The selected device may be a parameterized cell (pcell), a part or component of a circuit whose structure is dependent on one or more parameters.

At S204, the process 200 receives a prompt regarding the device. The prompt may include, for example, one or more of an indication of an application the circuit is intended for, an indication of an environment the circuit it intended to operate in, indications of voltage and frequencies used in the circuit, performance goals for the circuit such as gain, gain-bandwidth product, signal to noise ratio, frequence response, distortion, and so on, a type of a portion of the circuit (i.e., a block) including the selected device (for example, power amplifier, low-noise amplifier, mixer, differential amplifier, comparator, and so on), and a size of the block, among others, and combinations thereof. The prompt may also include, for example, other words that may be associated with the circuit being designed and that may be recognized by the ML model 20.

At S206, the process 200 provides the partial input and the prompt to the ML model 20. The process 200 may also provide pertinent information from the design database 12 about the design and the selected device. Based on the information provided, the ML model 20 generates values for some or all of the parameters of the device for which values have not already been determined. The values for the parameters provided by the ML model 20 may include pcell parameter values, layout information, or both for the device, but embodiments are not limited thereto.

The ML model 20 is a generative artificial intelligence (AI) model trained on training data in the training database 18 that was derived from previous designs of analog circuits. The training data may be specific to the user or entity employing the user, may be provided along with a library of designs from a circuit design vendor, may be provided by a foundry, or combinations thereof.

The training database 18 may be selected from a plurality of specific training databases. For example, training databases may be specific to certain design domains (e.g., ultra-low power, gigahertz circuits, high power circuits, and so on). Training databases may also be specific to an organization, specific to a process technology, and so on.

Each training database may include information for a plurality of design blocks (hereinafter blocks), the information for each block including a corresponding name, a number of different types of devices in the design, parameters and associated values for the devices in the block including pre-layout parameters, post-layout parameters, and so on.

The information for each block may also include simulation setups and results for the block.

The information for each block may also include design rule check (DRC) decks used to validate the design. In embodiments, only “clean” blocks that conform to their respective DRC deck are included in the training database.

The information for each block may also include names of devices in the block.

The information for each block may also include locations of “hotspots” for parasitics in the device if any. Hotspots refers to physical locations in the block wherein a property of the device, such as a parasitic inductance, parasitic capacitance, or thermal density, exceeds a threshold. In embodiments, only blocks without hotspots are included in the training database.

The information for each block may also include the connectivity for each block, including a number of inputs, outputs, or both of the block.

At S208, the process 200 provides the parameter values determined by the ML model 20 to the user and provides the user with an opportunity to indicate acceptance or rejection each or all of the parameter values determined by the ML model 20.

At S208, the process 200 may also provide additional information generated by the ML model 20, beyond just values for the parameters of the device. For example, in embodiments, the ML model may also produce information indicating a simulation setup for the device which may then be provided to the user.

At S210, if the process 200 receives an indication of acceptance of the parameter values determined by the ML model 20, the process 200 proceeds to S212. Otherwise, if the process 200 receives an indication that one or more of the parameter values determined by the ML are rejected, the process 200 proceeds to S214.

At S212, the process 200 updates an accuracy metric for the ML model 20 to reflect that it had produced acceptable values for the parameters it determined, which may result in the ML model 20 having a higher accuracy metric. The process 200 then exits.

At S214, the process 200 updates an accuracy metric for the ML model 20 to reflect that it had produced rejected values for the parameters it determined, which may result in the ML model 20 having a lower accuracy metric. The process 200 then returns to S202.

When returning to S202, the process 200 may update the partial input to include the parameter values, if any, accepted by the user at S210. In embodiments, the process 200 may also provide the user with an opportunity to set additional parameter values or alter parameter values previously supplied by the user or by the ML model 20. The process 200 then proceeds again to S204.

At each iteration of S204, the process 200 may present the user with the previous prompt and may provide the user an opportunity to modify that prompt or provide a new one. The process 200 then proceeds again to S206.

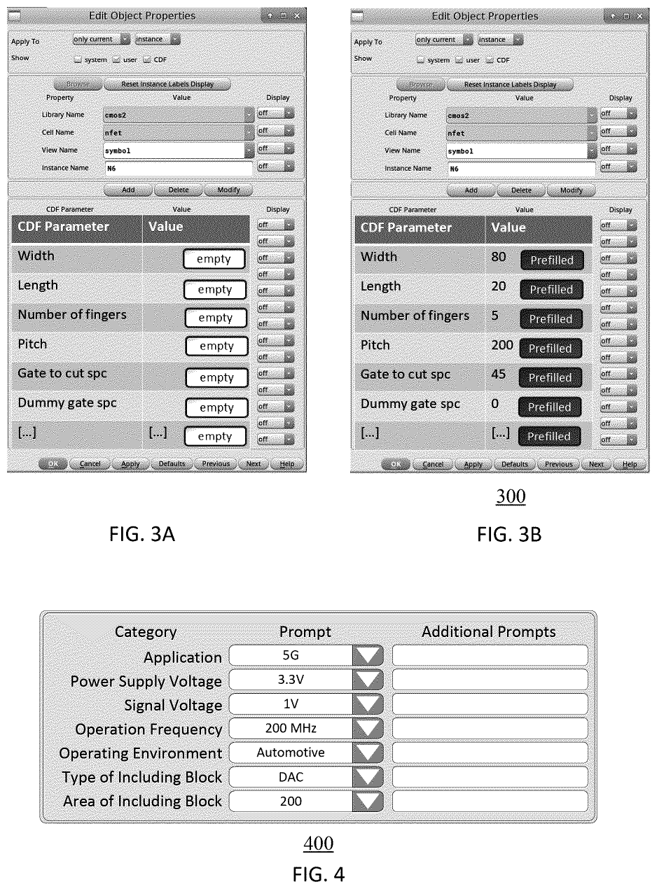

FIG. 3A illustrates an interface for setting parameter values for an instance of a device in an EDA system according to the related arts.

In the related arts system, the designer has to fill in all parameters according to the current function of the device. There may be up to 150 parameters for each instance of a device, and a design may have several thousand instances.

FIG. 3B illustrates an interface for setting parameter values for an instance of a device according to an embodiment.

Because the ML model 20 is a generative AI model, the ML model 20 may provide values for all the parameters of the device based on zero or more values provided in a partial input and on the contents of a prompt provided to the ML model 20. Accordingly, determining the parameters of all the instance may be done more quickly and with fewer opportunities for accidental error.

FIG. 4 includes an interface 400 according to an embodiment through which a process such as the process 200 of FIG. 2 may receive a prompt.

As shown in FIG. 4, the interface 400 includes a set of prompt categories and a drop-down menu for selecting from among common values for each category. The categories and their respective common values may be determined according to the occurrence of category values in the training database 18.

The interface 400 may also include fields for inputting one or more “free form” values for each category, which the ML model 20 may be able to use as inputs.

Embodiments of the present disclosure accelerate the design process, reducing the amount of time typically needed to produce a design, in a manner similar to how predictive text can accelerate writing.

Embodiments may also encourage the creation of more standardized designs, and thereby improve the quality of the designs.

Embodiments may also allow inexperienced designers to create designs they would otherwise be incapable of creating by selecting values for parameters that an inexperienced designer would not know how to select. Furthermore, the training of inexperienced designers may be accelerated by having them observe the operation the ML model.

Aspects of the present disclosure have been described in conjunction with the specific embodiments thereof that are proposed as examples. Numerous alternatives, modifications, and variations to the embodiments as set forth herein may be made without departing from the scope of the claims set forth below. Accordingly, embodiments as set forth herein are intended to be illustrative and not limiting.

1. A method for performing semiconductor design performed by a computer, the method comprising:
receiving an indication of a device comprising a parameterized cell (pcell);
receiving a prompt regarding the device; and
producing, using a trained machine learning (ML) model and based on the indication of the device and the prompt, a first value for a first parameter of the device.

2. The method of claim 1, wherein the trained ML model is a generative artificial intelligence (AI) ML model.

3. The method of claim 1, further comprising:
receiving a partial input including a second value for a second parameter of the device, and
producing, using the trained ML model and based on the indication of the device, the prompt, and the partial input, the first value for the first parameter of the device.

4. The method of claim 1, further comprising:
communicating, using a user interface, a message including the first value;
receiving, using the user interface, a response corresponding to the message;
when the response indicates that the first value is accepted, setting the first parameter to the first value; and
when the response indicates that the first value is rejected, producing, using the trained ML model and based on the indication of the device and the prompt, a second value for the first parameter of the device.

5. The method of claim 4, further comprising updating an accuracy metric of the trained ML model according to whether the first value was accepted.

6. The method of claim 1, further comprising:
producing, using the trained ML model and based on the indication of the device and the prompt, the first value for the first parameter of the device and a second value for a second parameter of the device;
communicating the message including the first value and the second value; and
when the response indicates that the first value is accepted and the second value is rejected, setting the first parameter to the first value and producing, using the machine learning (ML) model and based on the indication of the device, the prompt, and the first value, a fourth value for the second parameter of the device.

7. The method of claim 1, wherein the prompt comprises an indication of an application, an indication of an operational environment, a voltage specification, a frequency specification, a bandwidth specification, a gain-bandwidth product specification, a voltage specification, an indication of a type of a block including the device, an indication of a size of the block, or a combination thereof.

8. The method of claim 1, wherein the first parameter is a parameter used to configure the pcell.

9. The method of claim 1, wherein the first parameter is a layout placement parameter or a parameter for setting up a simulator.

10. The method of claim 1, wherein the trained ML model corresponds to a model trained using a learning database, the learning database comprising a plurality of entries, each entry comprising a block name, a number of different types of devices in the block, a parameter and corresponding value for the block, a simulation setup and corresponding simulation result for the block, a connectivity, a design rule check (DRC) deck corresponding to the block, a device name of a device in the block, information on parasitics in the block, or a combination thereof.

11. A non-transient computer-readable medium (CRM) comprising computer programming instructions which, when executed by a computer, cause the computer to perform steps of a process for semiconductor design, the steps comprising:
receiving an indication of a device comprising a parameterized cell (pcell);
receiving a prompt regarding the device; and
producing, using a trained machine learning (ML) model and based on the indication of the device and the prompt, a first value for a first parameter of the device.

12. The method of claim 11, wherein the trained ML model is a generative artificial intelligence (AI) ML model.

13. The method of claim 11, further comprising:
receiving a partial input including a second value for a second parameter of the device, and
producing, using the trained ML model and based on the indication of the device, the prompt, and the partial input, the first value for the first parameter of the device.

14. The method of claim 11, further comprising:
communicating, using a user interface, a message including the first value;
receiving, using the user interface, a response corresponding to the message;
when the response indicates that the first value is accepted, setting the first parameter to the first value; and
when the response indicates that the first value is rejected, producing, using the trained ML model and based on the indication of the device and the prompt, a second value for the first parameter of the device.

15. The method of claim 14, further comprising updating an accuracy metric of the trained ML model according to whether the first value was accepted.

16. The method of claim 11, further comprising:
producing, using the trained ML model and based on the indication of the device and the prompt, the first value for the first parameter of the device and a second value for a second parameter of the device;
communicating the message including the first value and the second value; and
when the response indicates that the first value is accepted and the second value is rejected, setting the first parameter to the first value and producing, using the machine learning (ML) model and based on the indication of the device, the prompt, and the first value, a fourth value for the second parameter of the device.

17. The method of claim 11, wherein the prompt comprises an indication of an application, an indication of an operational environment, a voltage specification, a frequency specification, a bandwidth specification, a gain-bandwidth product specification, a voltage specification, an indication of a type of a block including the device, an indication of a size of the block, or a combination thereof.

18. The method of claim 11, wherein the first parameter is a parameter used to configure the pcell.

19. The method of claim 11, wherein the first parameter is a layout placement parameter or a parameter for setting up a simulator.

20. The method of claim 11, wherein the trained ML model corresponds to a model trained using a learning database, the learning database comprising a plurality of entries, each entry comprising a block name, a number of different types of devices in the block, a parameter and corresponding value for the block, a simulation setup and corresponding simulation result for the block, a connectivity, a design rule check (DRC) deck corresponding to the block, a device name of a device in the block, information on parasitics in the block, or a combination thereof.
